(19) United States
(12) Patent Application Publication
(10) Pub. No.: US 2026/0354134 A1
(43) Pub. Date: Nov. 5, 2026

(54) STRESS MODULATION USING STI CAPPING LAYER FOR REDUCING FIN BENDING

(71) Applicant: Taiwan Semiconductor Manufacturing Co., Ltd., Hsinchu Science Park (TW)

(72) Inventors: Wan-Yi Kao, Baoshan Township (TW); ChunYao Wang, Zhubei City (TW); Yung-Cheng Lu, Hsinchu (TW)

(21) Appl. No.: 19/734,289

(22) Filed: Jul. 8, 2026

Related U.S. Application Data
(63) Continuation of application No. 17/658,125, filed on Apr. 6, 2022.
(60) Provisional application No. 63/289,701, filed on Dec. 15, 2021.

(51) Int. Cl. H10W 10/00; H10P 14/60; H10P 95/90; H10W 10/17

(52) U.S. Cl. CPC H10W 10/014; H10P 14/6339; H10P 95/90; H10W 10/17

(57) ABSTRACT

A method includes etching a semiconductor substrate to form a semiconductor strip and a recess, with a sidewall of the semiconductor strip being exposed to the recess, depositing a dielectric layer into the recess, and depositing a capping layer over the dielectric layer. The capping layer extends into the recess, and comprises silicon oxynitride. The method further includes filling remaining portions of the recess with dielectric materials, performing an anneal process to remove nitrogen from the capping layer, and recessing the dielectric materials, the capping layer, and the dielectric layer. The remaining portions of the dielectric materials, the capping layer, and the dielectric layer form an isolation region. A portion of the semiconductor strip protrudes higher than a top surface of the isolation region to form a semiconductor fin.

### PRIORITY CLAIM AND CROSS-REFERENCE

This application is a continuation of U.S. Patent Application No. 17/658,125, entitled “STRESS MODULATION USING STI CAPPING LAYER FOR REDUCING FIN BENDING,” filed on Apr. 6, 2022, which claims the benefit of the following provisionally filed U.S. Patent application: Application No. 63/289,701, filed on Dec. 15, 2021, and entitled “MSM LNSK1 for Fin Bending and Device Gain,” which application are hereby incorporated herein by reference.

### BACKGROUND

With the increasing down-scaling of integrated circuits and the increasingly demanding requirements to the speed of integrated circuits, transistors need to have higher drive currents with increasingly smaller dimensions. Fin Field-Effect Transistors (FinFETs) were thus developed. The FinFETs include vertical semiconductor fins above a bulk substrate. The semiconductor fins are used to form source and drain regions, and to form channel regions between the source and drain regions. Shallow Trench Isolation (STI) regions are formed to define the semiconductor fins. The FinFETs also include gate stacks, which are formed on the sidewalls and the top surfaces of the semiconductor fins.

In the formation of the STI regions and the respective FinFETs, STI regions are first formed, and then recessed to form semiconductor fins, based on which the FinFETs are formed. The formation of STI regions may include forming an isolation liner, and then forming an oxide region over the isolation liner using flowable chemical vapor deposition.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-2, 3A, 3B, 4-6, 7A, 7B, 8, 9A, 9B, 10A, 10B and 10C and 10C illustrate the cross-sectional views and perspective view of intermediate stages in the formation of FinFETs in accordance with some embodiments.

FIG. 11 illustrates an Atomic Layer Deposition (ALD) cycle in the formation of a SiON film in accordance with some embodiments.

FIGS. 12A and 12B illustrate a schematic structure of a Shallow Trench Isolation (STI) capping layer as deposited in accordance with some embodiments.

FIGS. 13A, 13B and 13C, illustrate a schematic structure of the STI capping layer after a low-temperature wet anneal process and a high-temperature wet anneal process are performed in accordance with some embodiments.

FIGS. 14A and 14B illustrate a schematic structure of the STI capping layer after a dry anneal process in accordance with some embodiments.

FIG. 15 illustrates two regions with separately formed STI capping layers in accordance with some embodiments.

FIG. 16 illustrates a schematic distribution profile of nitrogen atomic percentage in accordance with some embodiments.

FIG. 17 illustrates a process flow for forming Fin Field-Effect Transistors (FinFETs) and dielectric fins in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Fin Field-Effect Transistors (FinFETs), isolation regions, and the method of forming the same are provided. In accordance with some embodiments of the present disclosure, a (nitrogen-containing) dielectric layer including nitrogen is deposited. The nitrogen-containing dielectric layer is capable of having its nitrogen being removed later through annealing. The nitrogen-containing dielectric layer has the ability of applying a stress to reduce semiconductor strip/fin bending. After the subsequent removal of nitrogen, the dielectric layer is converted into a silicon oxide layer, which has low leakage due to the low charge-trapping ability of silicon oxide. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

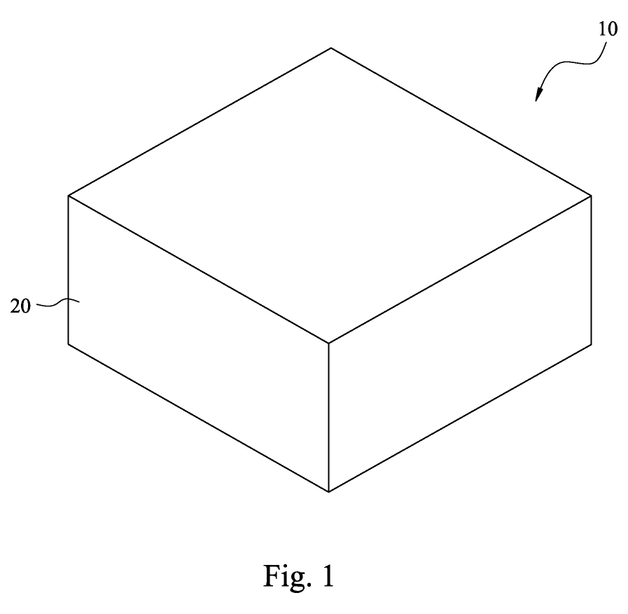

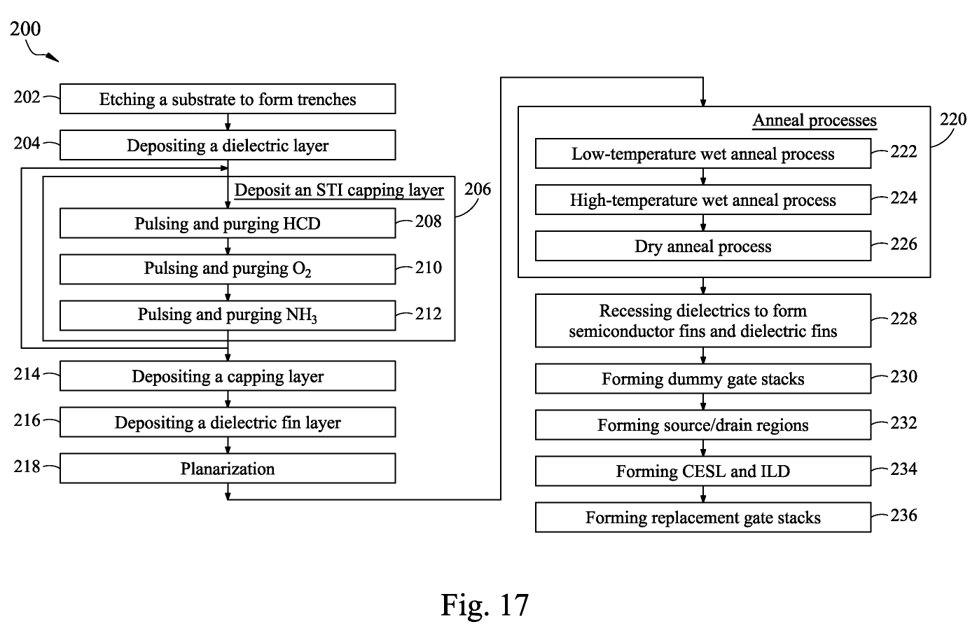

FIGS. 1-2, 3A, 3B, 4-6, 7A, 7B, 8, 9A, 9B, 10A, 10B and 10C, illustrate the cross-sectional views of intermediate stages in the formation of FinFETs and adjacent dielectric fins in accordance with some embodiments of the present disclosure. The corresponding processes are also reflected schematically in the process flow 200 as shown in FIG. 17.

Referring to FIG. 1, substrate 20 is provided. The substrate 20 may be a semiconductor substrate, such as a bulk semiconductor substrate, a Semiconductor-On-Insulator (SOI) substrate, or the like, which may be doped (e.g., with a p-type or an n-type dopant) or undoped. The semiconductor substrate 20 may be a part of wafer 10, such as a silicon wafer. Generally, an SOI substrate is a layer of a semiconductor material formed on an insulator layer. The insulator layer may be, for example, a Buried Oxide (BOX) layer, a silicon oxide layer, or the like. The insulator layer is provided on a substrate, typically a silicon or glass substrate. Other substrates such as a multi-layered or gradient substrate may also be used. In some embodiments, the semiconductor material of semiconductor substrate 20 may include silicon; germanium; a compound semiconductor including carbon-doped silicon, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

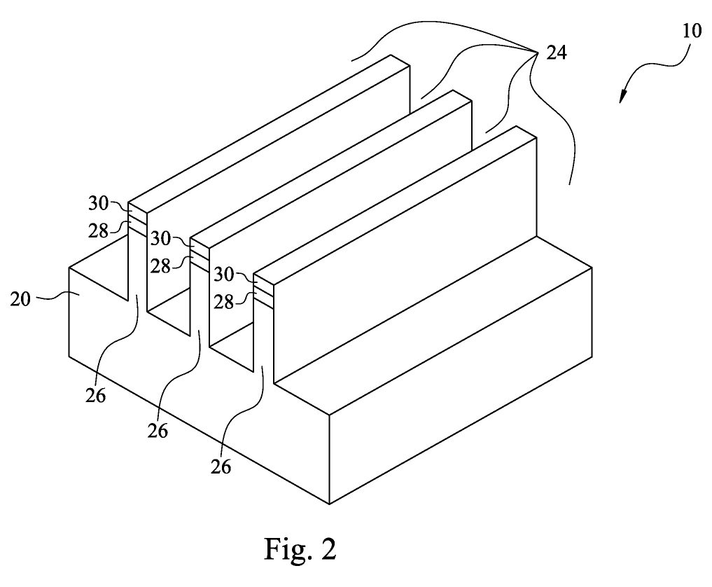

Referring to FIG. 2, substrate 20 is etched to form trenches 24. The respective process is illustrated as process 202 in the process flow 200 as shown in FIG. 17. The portions of substrate 20 between neighboring trenches 24 are referred to as semiconductor strips 26 hereinafter. To form trenches 24, pad oxide layer 28 and hard mask layer 30 are formed on semiconductor substrate 20, and are then patterned. Pad oxide layer 28 may be a thin film formed of silicon oxide. In accordance with some embodiments of the present disclosure, pad oxide layer 28 is formed in a thermal oxidation process, wherein a top surface layer of semiconductor substrate 20 is oxidized.

In accordance with some embodiments of the present disclosure, hard mask layer 30 is formed of silicon nitride, for example, using Low-Pressure Chemical Vapor Deposition (LPCVD), Plasma Enhanced Chemical Vapor Deposition (PECVD), Atomic Layer Deposition (ALD), or the like. A photoresist (not shown) is formed on hard mask layer 30 and is then patterned. Hard mask layer 30 is then patterned using the patterned photoresist as an etching mask to form hard masks 30 as shown in FIG. 2. Next, the patterned hard mask layer 30 is used as an etching mask to etch pad oxide layer 28 and substrate 20, forming trenches 24.

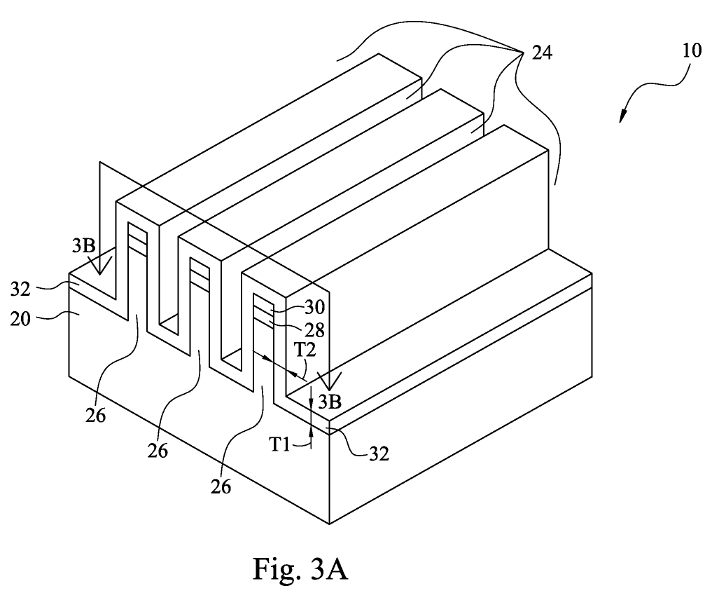

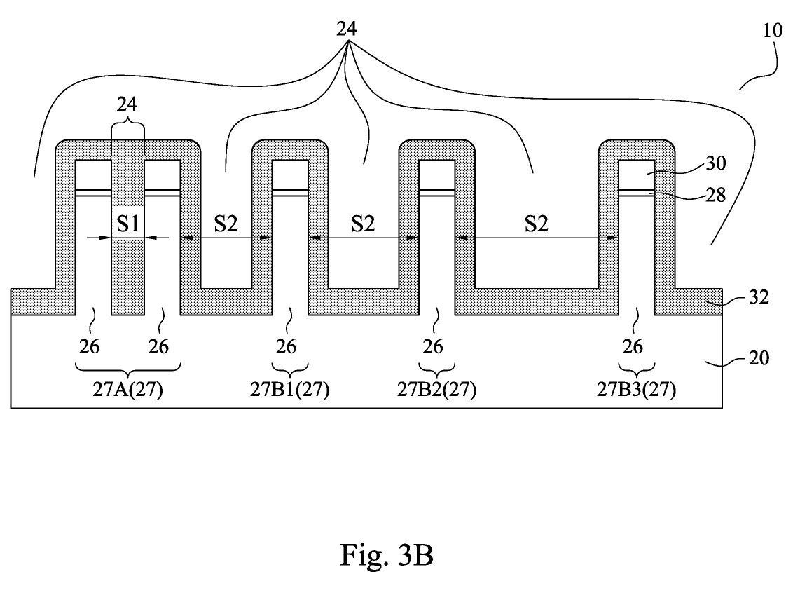

Referring to FIG. 3A, dielectric layer 32 is deposited. The respective process is illustrated as process 204 in the process flow 200 as shown in FIG. 17. In accordance with some embodiments of the present disclosure, dielectric layer 32 is formed using a conformal deposition process such as ALD, Chemical Vapor Deposition (CVD), or the like. Accordingly, the horizonal thickness T1 of the horizontal portions and vertical thickness T2 of the vertical portions of dielectric layer 32 are equal to or substantially equal to each other, for example, with a variation smaller than about 10 percent. The material of dielectric layer 32 may be selected from silicon oxide, silicon nitride, silicon oxynitride, silicon oxy-carbo-nitride, hafnium oxide, zirconium oxide, aluminum oxide, and the like, and combinations thereof. Dielectric layer 32 may also be a composite layer including a plurality of sub layers, which are formed of different materials. The thicknesses T1 and T2 may be greater than about 5 nm, and may be in the range between about 2 nm and about 20 nm. In accordance with some example embodiments, dielectric layer 32 may be formed of silicon oxide, with a nitrogen atomic percentage lower than about 5 percent, lower than about 2 percent, or in the range between about 0.1 percent and about 2 percent. Dielectric layer 32 as deposited may also be free from nitrogen therein.

FIG. 3B illustrates the cross-section 3B-3B in FIG. 3A. It is appreciated that FIG. 3A is schematic, and do not include all of the details as shown in FIG. 3B. Throughout the description, the semiconductor strips 26 that are closely located from each other are collectively referred to as a semiconductor strip group 27, and FIG. 3B illustrate example semiconductor strip groups 27A, 27B1, 27B2, and 27B3. For example, FIG. 3B illustrates some semiconductor strips 26 closely located from each other to form a semiconductor strip group 27A. The semiconductor strips in the same group may be used for forming the same FinFET. Although FIG. 3B illustrates that semiconductor strip group 27A includes two semiconductor strips 26, there may be more semiconductor strips in a semiconductor strip group. The inner-group spacings S1 between the semiconductor strips 26 in the same strip group 27 are smaller than the inter-group spacings S2 between neighboring semiconductor strip groups 27. There may also be some single-fin semiconductor strip groups, with each group including a single fin. Some example single-fin semiconductor strip groups 27 (such as semiconductor strip groups 27B1, 27B2, and 27B3) are shown.

As a result of the conformal deposition of dielectric layer 32, the trenches 24 between the semiconductor strips 26 in the same semiconductor strip group 27 are fully filled. On the other hand, the trenches 24 between semiconductor strip groups 27 are partially filled. After the deposition of STI capping layer 34, dielectric layer 32 may be exposed to the moisture in the air. Due to the formation of native oxide and the exposure to moisture, Si-OH bonds are formed at the surface of dielectric layer 32.

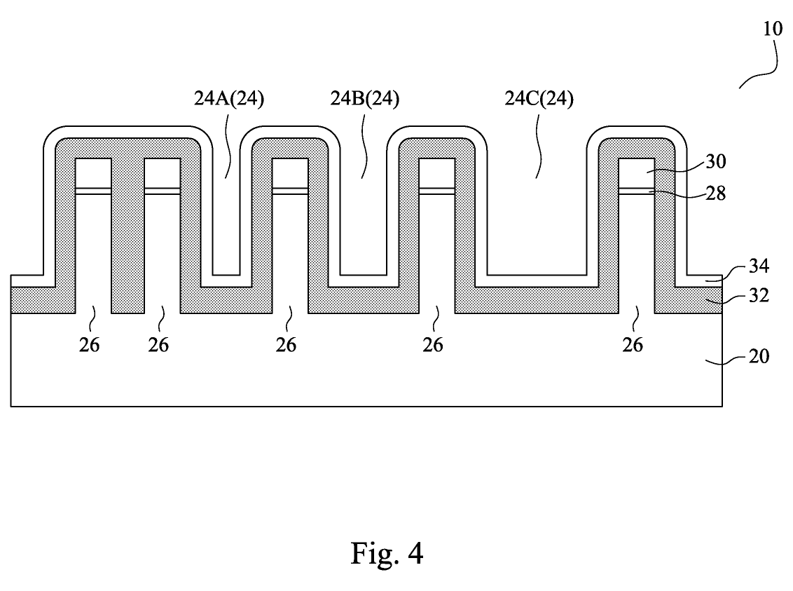

FIG. 4 illustrates the formation of dielectric layer 34, which is alternatively referred to as Shallow Trench Isolation (STI) capping layer 34. The respective process is illustrated as process 206 in the process flow 200 as shown in FIG. 17. In the beginning of the deposition process, wafer 10 is placed in an Atomic Layer Deposition (ALD) chamber (not shown), in which one or a plurality of ALD cycles are performed to grow STI capping layer 34 conformally.

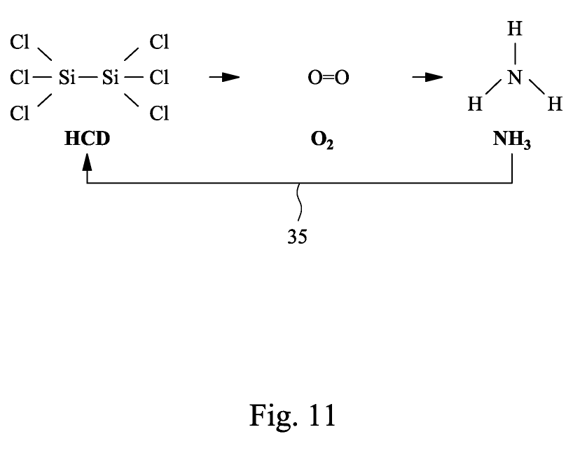

FIG. 11 schematically illustrates the intermediate stages in an ALD cycle 35 and the repeating of the ALD cycle. In the beginning of the ALD cycle, Hexachlorodisilane (HCD) is introduced/pulsed into the ALD chamber (not shown), in which wafer 10 (FIGS. 3A and 3B) is placed. The respective process is illustrated as process 208 in the process flow 200 as shown in FIG. 17. HCD has the chemical formula of (SiCl₃)₂, and the chemical structure of an HCD molecule is shown in FIG. 11. An HCD molecule includes six chlorine atoms bonded to two silicon atoms. When HCD is pulsed into the ALD chamber, wafer 10 is heated, for example, to a temperature in the range between about 450°C and about 700°C. The OH bonds at the surface of dielectric layer 32 are broken, and silicon atoms along with the chlorine atoms bonding to them are bonded to the dangling oxygen atoms to form O-Si-Cl bonds. In accordance with some embodiments, the flow rate of HCD may be in the range between about 0.1 slm and about 2 slm, for example, in the range between about 0.3 slm and about 0.6 slm. The pressure in the ALD chamber may be in the range between about 60 pa and about 1,000 pa, and may be in the range between about 100 pa and about 120 pa. The pulsing duration may be in the range between about 5 seconds and about 50 seconds, and may be in the range between about 15 seconds and about 25 seconds.

Next, HCD is purged from the ALD chamber. Referring to FIG. 11, oxygen (O₂) is pulsed into the ALD chamber. The respective process is illustrated as process 210 in the process flow 200 as shown in FIG. 17. The previously formed structure reacts with oxygen, and some of the Si-Cl bonds are broken, and are connected to oxygen atoms to form Si-O bonds. In accordance with some embodiments, the flow rate of oxygen may be in the range between about 0.5 slm and about 10 slm, and may be in the range between about 2.0 slm and about 8.0 slm. The pressure may be in the range between about 60 pa and about 2,000 pa, and may be in the range between about 1,000 pa and about 1,400 pa. The pulsing duration may be in the range between about 30 seconds and about 100 seconds, and may be in the range between about 50 seconds and about 70 seconds. Oxygen is then purged.

Next, as also shown in FIG. 11, ammonia is pulsed into the ALD chamber. The respective process is illustrated as process 212 in the process flow 200 as shown in FIG. 17. The previously formed structure reacts with ammonia. Some of the Si-Cl bonds are broken, and are connected to NH₂ to form Si-NH₂ bonds. In accordance with some embodiments, the flow rate of ammonia may be in the range between about 0.5 slm and about 10 slm, and may be in the range between about 2.0 slm and about 8.0 slm. The pressure may be in the range between about 100 pa and about 1,200 pa, and may be in the range between about 800 pa and about 1,000 pa. The pulsing duration may be in the range between about 30 seconds and about 100 seconds, and may be in the range between about 15 seconds and about 20 seconds. Ammonia is then purged. An atomic layer of STI capping layer 34 is thus deposited.

After the ammonia is purged, the ALD cycle 35 may be repeated, so that a plurality of atomic layers are deposited to form STI capping layer 34, as shown in FIG. 4. Each of the ALD cycles 35results in a layer of SiON being deposited. For example, the thickness of an atomic layer of the deposited SiON may be in the range between about 0.5 Å and about 4.0 Å, and may be around 1.5 Å and about 2.5 Å. When the deposition process is finished, the deposited STI capping layer 34 may have a thickness in the range between about 1 nm and about 5 nm.

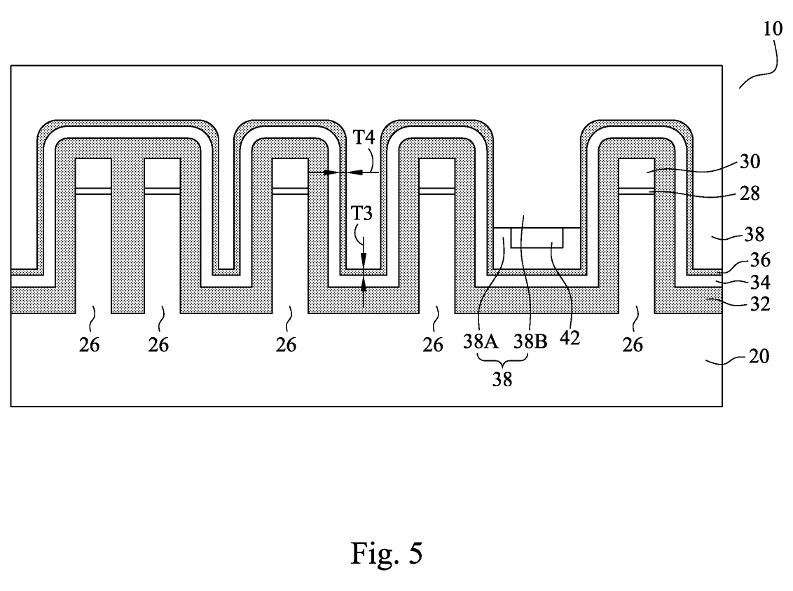

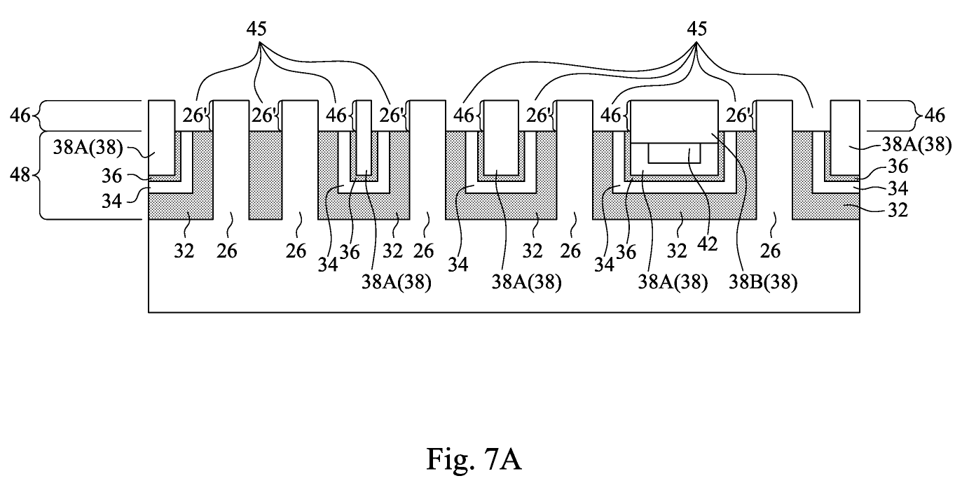

Referring to FIG. 5, dielectric capping layer 36 is formed. The respective process is illustrated as process 214 in the process flow 200 as shown in FIG. 17. In accordance with some embodiments of the present disclosure, dielectric capping layer 36 is formed using a conformal deposition method such as Atomic Layer Deposition (ALD) or CVD. Accordingly, the horizontal thickness T3 of the horizontal portions and the vertical thickness T4 of the vertical portions of dielectric capping layer 36 are equal to or substantially equal to each other, for example, with a variation smaller than about 10 percent. The material of dielectric capping layer 36 may be selected from silicon oxide, Phospho-Silicate Glass (PSG), Boro-Silicate Glass (BSG), Boron-Doped Phospho-Silicate Glass (BPSG), or the like. Dielectric capping layer 36 may have a nitrogen atomic percentage significantly lower than the nitrogen atomic percentage of STI capping layer 34. For example, the nitrogen atomic percentage of dielectric capping layer 36 may be lower than about 2 percent or 1 percent. Dielectric capping layer 36 has the function of adjusting the width of the subsequent formed dielectric hybrid fin 46 (FIG. 7A).

Dielectric fin layer 38 is then formed over dielectric capping layer 36. The respective process is illustrated as process 216 in the process flow 200 as shown in FIG. 17. Dielectric fin layer 38 is formed using a method that has good gap-filling capability. In accordance with some embodiments of the present disclosure, dielectric fin layer 38 is formed through High-density Plasma Chemical Vapor Deposition (HDPCVD), PECVD, ALD, or the like. The material of dielectric fin layer 38 is different from the material of dielectric layers 34 and 36. In accordance with some embodiments, dielectric fin layer 38 is formed of or comprises a high-k dielectric material such as hafnium oxide, zirconium oxide, aluminum oxide, aluminum nitride, titanium nitride, or the like, combinations thereof, or multi-layers thereof. Alternatively, dielectric fin layer 38 may be formed of silicon oxide, silicon carbide, silicon carbo-nitride, silicon oxynitride, silicon oxy carbo-nitride, BSG, PSG, BPSG, or the like. Dielectric fin layer 38 fully fills the trenches 24 (FIG. 4).

FIG. 5 also illustrates the formation of dielectric region 42, which may be formed to fill very wide trenches that are difficult to be filled by dielectric fin layer 38. The formation of dielectric fin layer 38 may include depositing dielectric fin layers 38A and 38B. In accordance with some embodiments, the formation process of dielectric fin layer 38A includes a conformal deposition process such as ALD, CVD, or the like, wherein the trench 24B (FIG. 4) is fully filled, while trench 24C is partially filled. Next, the remaining trench 24C is filled with a dielectric material such as a flowable oxide, which fully fills the remaining trench 24C. A planarization process and an etch-back process are then performed to recess dielectric fin layer 38A and the dielectric material 42, and dielectric region 42 is left. In a subsequent process, dielectric fin layer 38B is deposited to fully fill trenches 24 (FIG. 4).

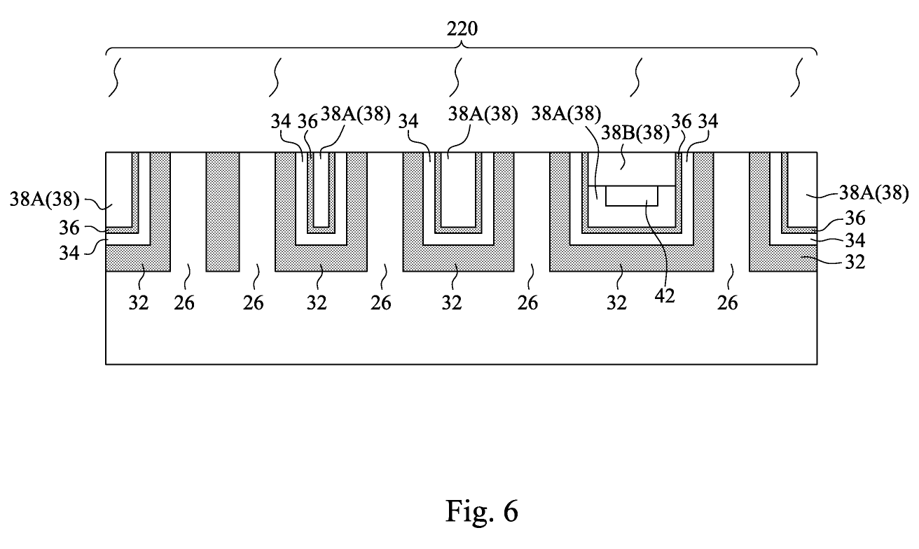

Next, as shown in FIG. 6, a planarization process such as a CMP process or a mechanical grinding process is performed, so that the top surface of dielectric fin layer 38 is planar. The respective process is illustrated as process 218 in the process flow 200 as shown in FIG. 17. The planarization process is then continued to remove the excess portions of dielectric fin layer 38 and dielectric layers 36, 34, and 32 higher than the top surfaces of semiconductor strips 26. Hard masks 30 and pad oxide layers 28 are also removed. As a result, the top edges of the sidewall (vertical) portions of dielectric layers 32, 34, 36, and 38 are exposed. In accordance with alternative embodiment, the planarization process is finished when the top surfaces of hard mask 30 are exposed.

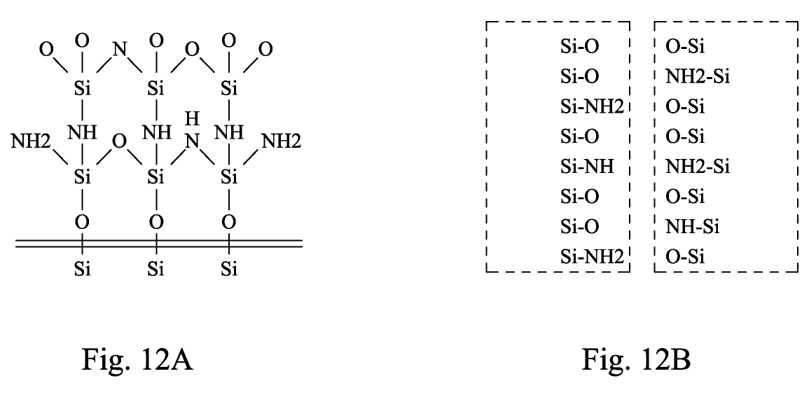

After the planarization process, an anneal process 220 is performed. The respective process is illustrated as process 220 in the process flow 200 as shown in FIG. 17. In accordance with some embodiments of the present disclosure, the anneal process 220 includes a low-temperature wet anneal process 222, a high-temperature wet anneal process 224, and a dry anneal process 226. The low-temperature wet anneal process 222 and high-temperature wet anneal process 224 may be performed using steam (H₂O) as the process gas. The dry anneal process 226 may be performed using nitrogen (N₂), argon, or the like as carrier gases. The anneal processes are discussed below referring to FIGS. 12A, 12B, 13A, 13B, 13C, 14A and 14B

FIG. 12A schematically illustrates a chemical structure of the STI capping layer 34, as deposited and before the anneal process 220, wherein two atomic layers are shown. FIG. 12B schematically illustrates another representation, wherein some example bonds in the two vertical sidewall portions of STI capping layer 34 are shown. In accordance with some embodiments of the present disclosure, the low-temperature wet anneal process is first performed. The respective process is illustrated as process 222 in the process flow 200 as shown in FIG. 17. The low-temperature wet anneal process 222 is performed at a relatively low temperature, which may be in the range between about 440°C and about 460°C. The low-temperature wet anneal process may last for a period of time in the range between about 3 hours and about 5 hours. The pressure during the low-temperature anneal may be about 1 atmosphere.

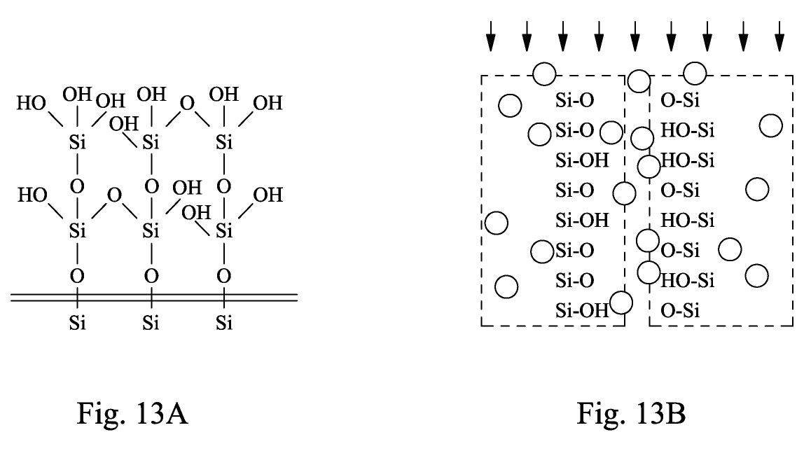

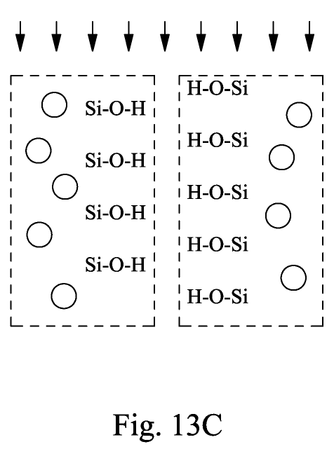

The low-temperature wet anneal process has two functions. The first function is to make the water/steam (H₂O) molecules to be diffused into the entire STI capping layer 34 through the exposed top edges of STI capping layer 34, wherein the solid dots in FIG. 13B represent the H₂O molecules. The second function is to partially convert the Si-N bonds, Si-CH₃ bonds, and Si-N-Si bonds in STI capping layer 34 into Si-OH bonds as shown in FIG. 13B. The temperature is controlled to be high enough to incur at least partial conversion.

After the low-temperature wet anneal process 222, the high-temperature wet anneal process is performed. The respective process is illustrated as process 224 in the process flow 200 as shown in FIG. 17. The high-temperature wet anneal process 224 is performed at a temperature higher than the temperature of the low-temperature wet anneal process. The anneal temperature may be in the range between about 525°C and about 575°C. The high-temperature wet anneal process 224 may last for a period of time in the range between about 1.5 hours and about 2.5 hours. The pressure of the high-temperature wet anneal process 224 may be about 1 atmosphere. The temperature is high enough to efficiently convert the Si-N bonds in STI capping layer 34 into Si-OH bonds, as schematically illustrated in FIGS. 13A and 13B. The high-temperature wet anneal process 224 results in the Si-N bonds (FIG. 12B) and Si-O bonds to be broken. Furthermore, the OH groups in H₂O are attached to the broken bonds. FIGS. 13A and 13C schematically illustrate the structure of the STI capping layer 34 after the low-temperature wet anneal process.

After the high-temperature wet anneal process 224, a dry anneal process is performed. The respective process is illustrated as process 226 in the process flow 200 as shown in FIG. 17. In the dry anneal process 226, an oxygen-free process gas such as nitrogen (N₂), argon, or the like may be used as the process gases. In accordance with some embodiments of the present disclosure, the dry anneal process 226 is performed at a temperature in the range between about 650°C and about 750°C. The dry anneal process may last for a period of time in the range between about 0.5 hours and about 1.5 hours. The pressure may be around 1 atmosphere.

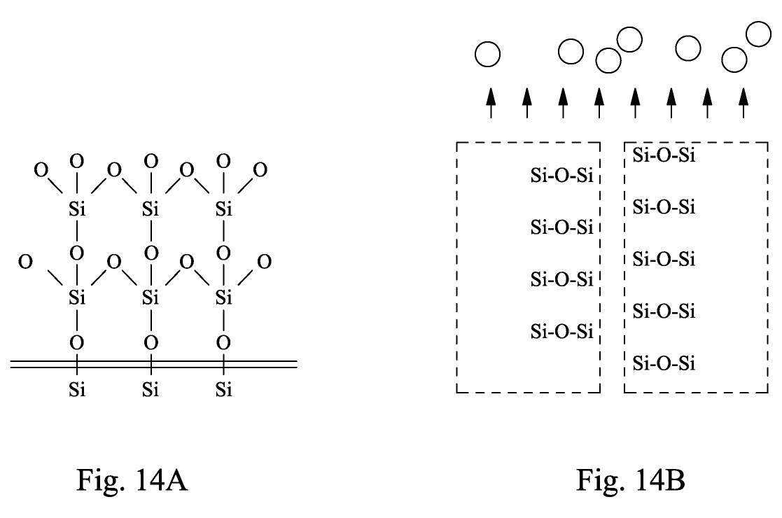

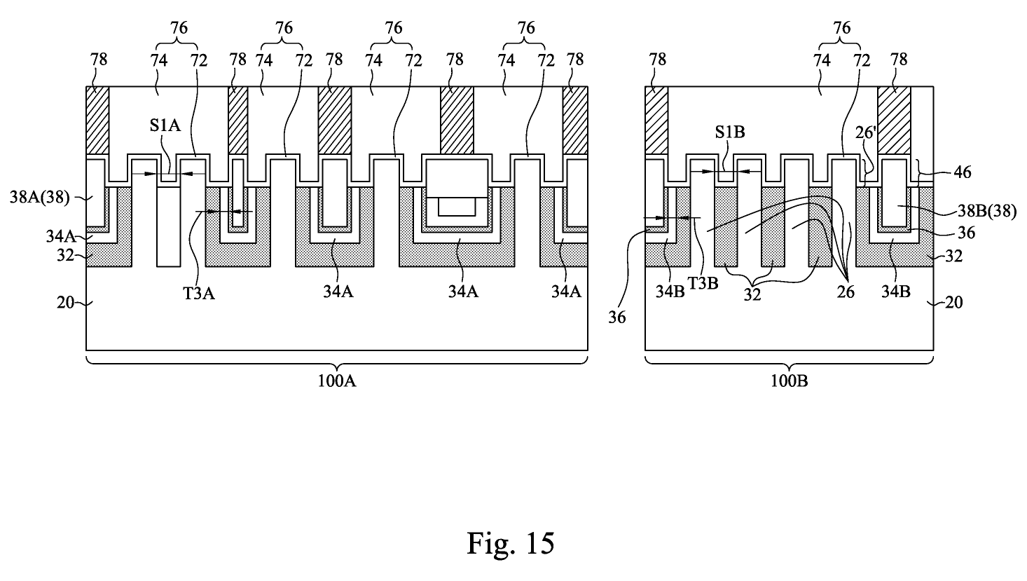

In the dry anneal process 226, the OH bonds and the Si-O bonds in STI capping layer 34 are broken, and the broken H and OH combine to form H₂O molecules, as represented by the dots in FIG. 14B. The oxygen atoms, whose bonds become dangling due to the loss of H atoms, may bond with Si to form silicon oxide (SiO₂). The respective chemical structure is also schematically illustrated in FIGS. 14A and 14B. Accordingly, the wet anneal processes and the dry anneal process convert the deposited silicon oxynitride layer into a silicon oxide layer. The generated H₂O molecules are carried away by the carrier gas.

As aforementioned, the STI capping layer 34 as deposited comprises SiON or SiONH, as shown in FIG. 12A. The inclusion of nitrogen in STI capping layer 34 may apply a stress to the structure shown in FIGS. 5 and 6, which stress prevents the bending of semiconductor strips 26. Otherwise, if the nitrogen-containing STI capping layer 34 is not formed, the semiconductor strips in the semiconductor strip groups 27 will bend. The semiconductor strips 26 (especially the outer strips) in the same fin group 27 will bend outwardly, which bending is caused by any anneal process performed. With the nitrogen-containing STI capping layer 34 being formed, the bending of semiconductor strips 26 is avoided.

An advantageous feature of the STI capping layer 34 is that its nitrogen can be removed by the anneal processes. Accordingly, during the anneal processes, STI capping layer 34 has achieved its function of preventing bending. Meanwhile, with the proceeding of the anneal process, its nitrogen is removed to form a silicon oxide layer. Although silicon oxide layer no longer has the function of preventing bending, the stress on the semiconductor strips 26 has been released after the anneal process, and semiconductor strips 26 will have no bending. The conversion of the SiON-containing STI capping layer 34 to the silicon-oxide-containing STI capping layer 34 is advantageous for reducing the leaking currents through STI region since silicon oxide has low leakage, while nitrogen-containing materials such as SiN and SiON have higher leakage. For example, after the anneal process 220, the effective charge density Qeff of the STI capping layer 34 may be reduced to lower than about 5E11 C/cm², and hence the leakage is low.

In accordance with some embodiments, before the anneal process 220 (and as deposited), STI capping layer 34 may have a silicon atomic percentage in the range between about 20 percent and about 40 percent (such as between about 18 percent and 22 percent). The oxygen atomic percentage may be in the range between about 30 percent and about 50 percent. The carbon atomic percentage may be lower than about 10 percent (such as 0 percent (without carbon)). The nitrogen atomic percentage may be in the range between about 5 percent and about 30 percent (such as between about 10 percent and 20 percent).

The anneal process 220 results in the increase in the oxygen atomic percentage and the reduction of nitrogen atomic percent. For example, after the anneal processes 220, STI capping layer 34 may have a silicon atomic percentage in the range between about 20 percent and about 40 percent (such as between about 18 percent and 22 percent). The oxygen atomic percentage may be in the range between about 50 percent and about 80 percent, and may be between about 65 percent and about 75 percent. The carbon atomic percentage may be lower than about 10 percent (such as 0 percent). The nitrogen atomic percentage may be reduced to be lower than about 10 percent (such as lower than about 2 percent). For example, 70 percent, 90percent, or more of the nitrogen may be removed.

FIGS. 7A and 7B illustrate the recessing of dielectric layers 32, 34, and 36 to form recesses 45. The respective process is illustrated as process 228 in the process flow 200 as shown in FIG. 17. The recessing may be performed using an isotropic etching process (such as a wet etching process or a dry etching process) or an anisotropic etching process (such as a dry etching process). The etching chemical (etching solution or etching gas) is selected so that dielectric layers 32, 34, and 36 are etched, while dielectric fin layer 38 is not etched.

As a result of the recessing of dielectric layers 32, 34, and 36, some portions of dielectric fin layer 38 protrude higher than the top surfaces of the remaining dielectric layers 32, 34, and 36 to form dielectric fins 46. Furthermore, semiconductor strips 26 have some top portions protruding higher than the top surfaces of the remaining dielectric layer 32 to form protruding semiconductor fins 26’. Throughout the description, the portions of dielectric layers 32, 34, and 36 and dielectric fin layer 38 below the corresponding protruding semiconductor fins 26’ and protruding dielectric fins 46 are referred to as Shallow Trench Isolation (STI) regions 48.

FIG. 7B schematically illustrates a perspective view, wherein FIG. 7A illustrates the cross-section of some portions of the structure shown in FIG. 7B, and the cross-section is obtained in a vertical plane.

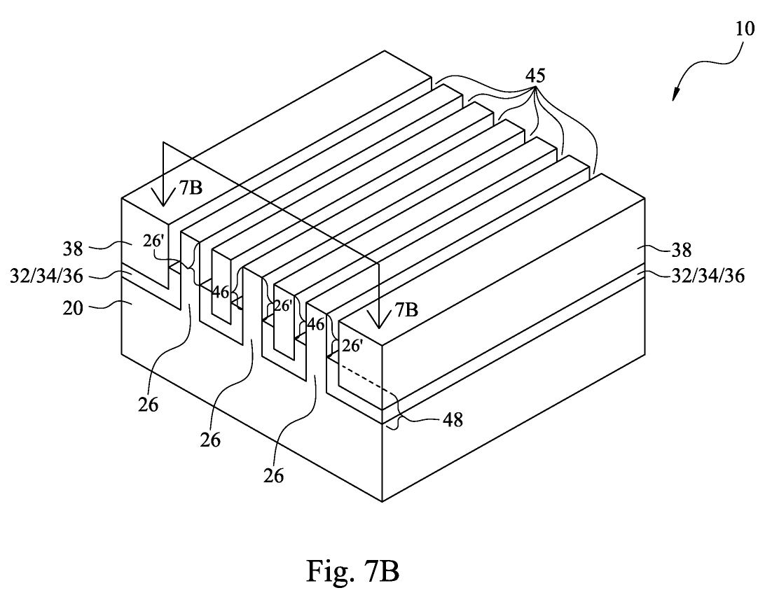

Referring to FIG. 8, dummy gate stacks 58 are formed to extend on the top surfaces and the sidewalls of protruding semiconductor fins 26’ and protruding dielectric fins 46. The respective process is illustrated as process 230 in the process flow 200 as shown in FIG. 17. Dummy gate stacks 58 may include dummy gate dielectrics 52 and dummy gate electrodes 54 over dummy gate dielectrics 52. Dummy gate dielectrics 52 may be formed of or comprise silicon oxide, and dummy gate electrodes 54 may be formed of or comprise amorphous silicon or polysilicon, while other applicable materials may also be used. Each of dummy gate stacks 58 may also include one (or a plurality of) hard mask layer 56 over dummy gate electrodes 54. Hard mask layers 56 may be formed of silicon nitride, silicon oxide, silicon carbo-nitride, silicon oxy-carbo-nitride, or multi-layers thereof. Dummy gate stacks 58 may cross over a plurality of protruding semiconductor fins 26’ and one or a plurality of protruding dielectric fins 46. Dummy gate stacks 58 also have lengthwise directions perpendicular to the lengthwise directions of protruding semiconductor fins 26’ and protruding dielectric fins 46.

The formation of dummy gate stacks 58 may include depositing a conformal gate dielectric layer, depositing a dummy gate electrode layer to fully fill the recesses 45 (FIG. 7B), planarizing the top surface of the dummy gate electrode layer, depositing hard mask layers on the planarized dummy gate electrode layer, and patterning the deposited layers.

Gate spacers 60 are formed on the sidewalls of dummy gate stacks 58. In accordance with some embodiments of the present disclosure, gate spacers 60 are formed of a dielectric material(s) such as silicon nitride, silicon oxy-nitride, silicon carbo-nitride, or the like, and may have a single-layer structure or a multi-layer structure including a plurality of dielectric layers. In accordance with some embodiments of the present disclosure, the formation of gate spacers 60 includes depositing a conformal spacer layer (which may be a single layer or a composite layer, not shown) on wafer 10, and then performing an anisotropic etching process to remove the horizontal portions of the spacer layer. The spacer layer is formed on the top surfaces and the sidewalls of dummy gate stacks 58, protruding semiconductor fins 26’, and protruding dielectric fins 46. Gate spacers 60 also have some portions extending into the recesses 45.

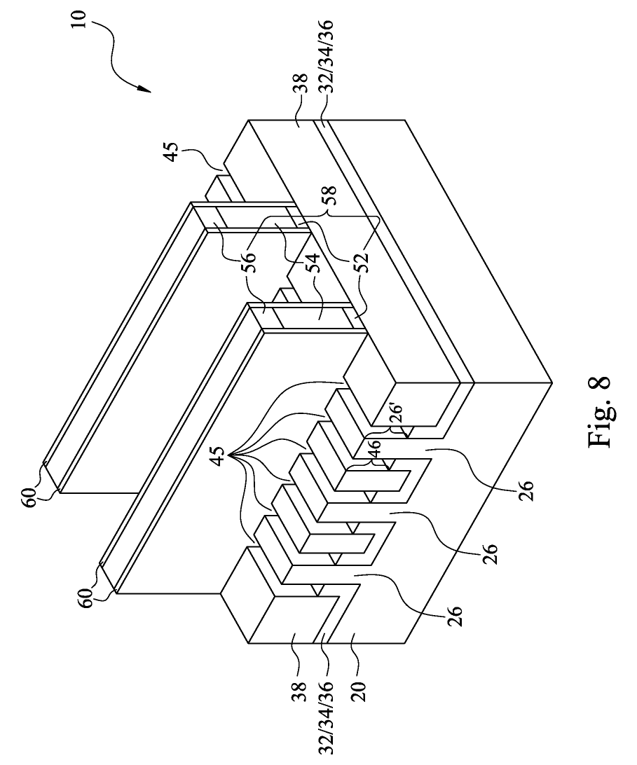

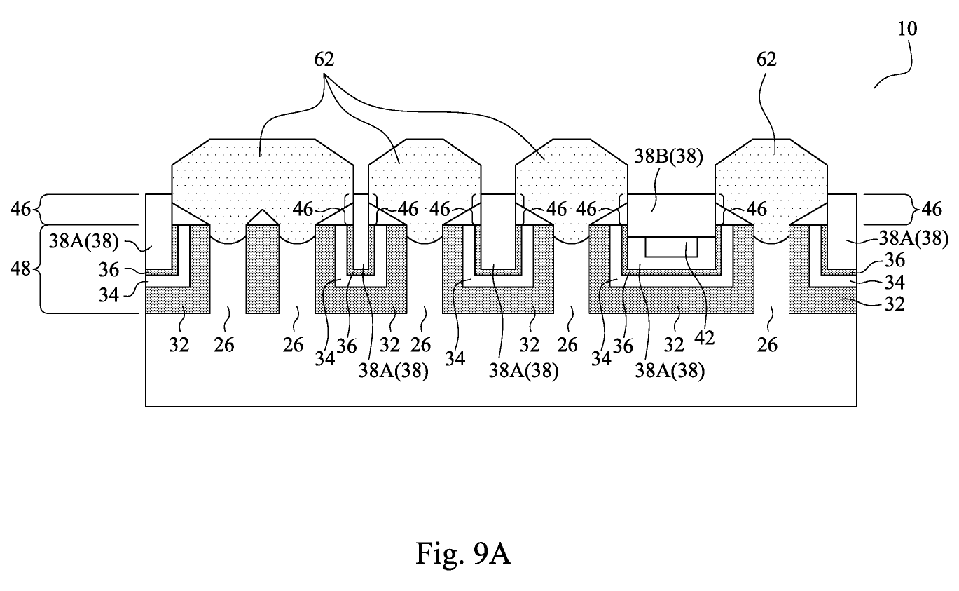

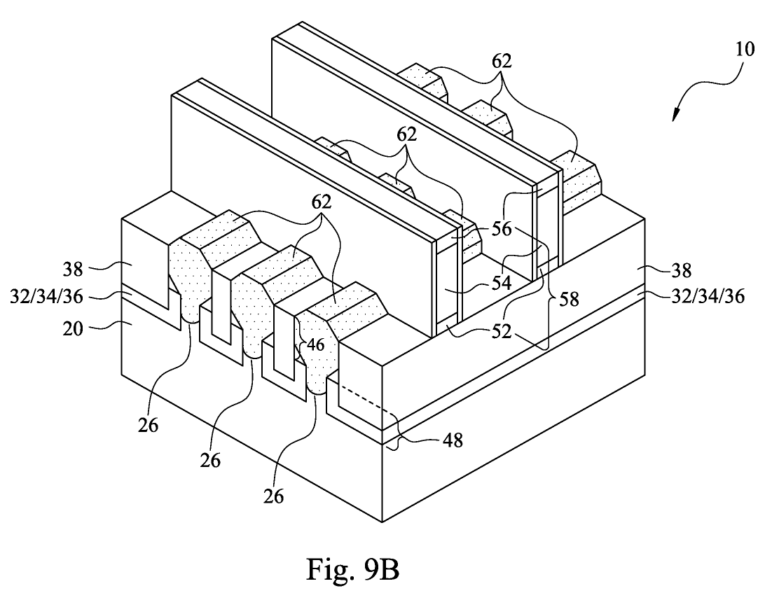

Next, as shown in FIGS. 9A and 9B, epitaxy regions (source/drain regions) 62 are formed. The respective process is illustrated as process 232 in the process flow 200 as shown in FIG. 17. In accordance with some embodiments, the formation process includes etching the portions of protruding semiconductor fins 26’ that are not protected by dummy gate stacks 58 and gate spacers 60 to form recesses, followed by selectively growing (through epitaxy) a semiconductor material in the recesses 45. Depending on whether the resulting FinFET is a p-type FinFET or an n-type FinFET, a p-type or an n-type impurity may be in-situ doped with the proceeding of the epitaxy. For example, when the resulting FinFET is a p-type FinFET, silicon germanium boron (SiGeB), silicon boron (SiB), or the like may be grown. Conversely, when the resulting FinFET is an n-type FinFET, silicon phosphorous (SiP), silicon carbon phosphorous (SiCP), or the like may be grown. In the epitaxy process, protruding dielectric fins 46 are used to limit the lateral growth of epitaxy source/drain regions 62, and to prevent neighboring source/drain regions 62 from merging with each other.

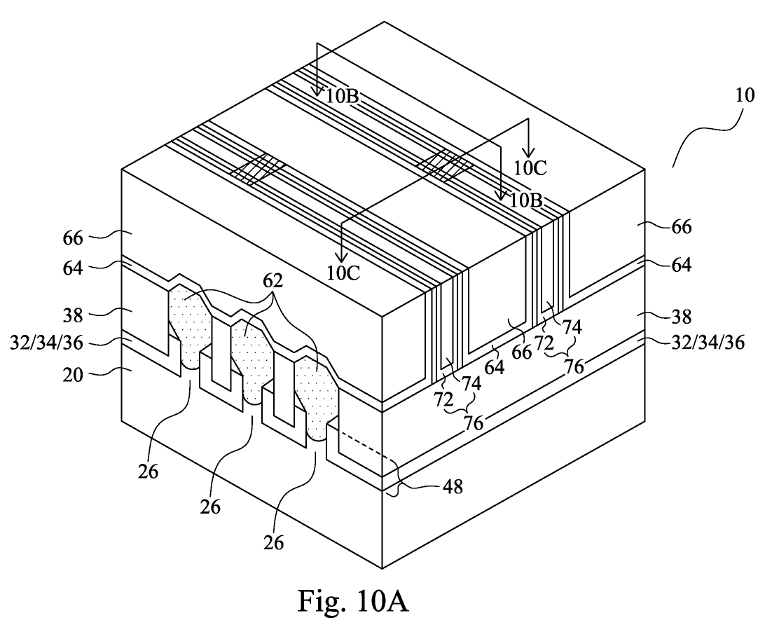

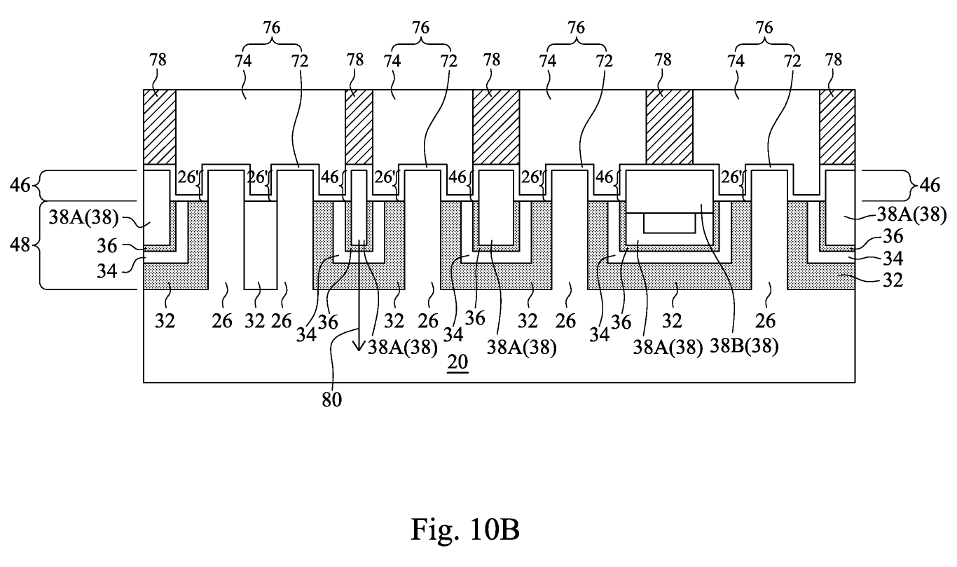

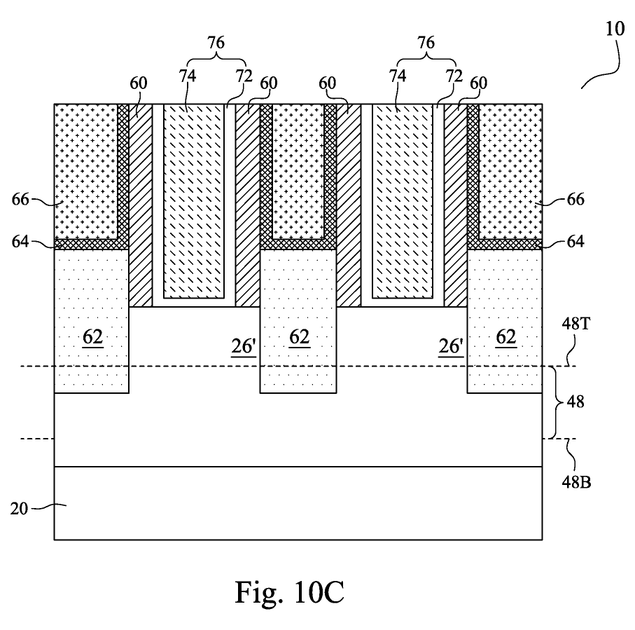

FIGS. 10A and 10C illustrate a perspective view and a cross-sectional view, respectively, of the structure after the formation of Contact Etch Stop Layer (CESL) 64 and Inter-Layer Dielectric (ILD) 66. The respective process is illustrated as process 234 in the process flow 200 as shown in FIG. 17. CESL 64 may be formed of silicon oxide, silicon nitride, silicon carbo-nitride, or the like, and may be formed using CVD, ALD, or the like. ILD 66 may include a dielectric material formed using, for example, FCVD, spin-on coating, CVD, or the like deposition method. ILD 66 may be formed of an oxygen-containing dielectric material, which may be silicon oxide, PSG, BSG, BPSG, or the like. A planarization process such as a CMP process or a mechanical grinding process may be performed to level the top surfaces of ILD 66, dummy gate stacks 58, and gate spacers 60 with each other.

Next, the dummy gate stacks 58 as shown in FIG. 9B are replaced with replacement gate stacks 76, as shown in FIGS. 10A, 10B, and 10C. The respective process is illustrated as process 236 in the process flow 200 as shown in FIG. 17. FIGS. 10B and 10C illustrate the cross-sections 10B-10B and 10C-10C, respectively in FIG. 10A. In the replacement process, the dummy gate stacks 58 (FIG. 9B) are etched, forming trenches between gate spacers 60. The top surfaces and the sidewalls of protruding semiconductor fins 26’ and dielectric fins 46 are exposed to the trenches. Next, replacement gate stacks 76 are formed in the trenches. Replacement gate stacks 76 include gate dielectrics 72 and gate electrodes 74.

In accordance with some embodiments of the present disclosure, a gate dielectric 72 includes an Interfacial Layer (IL) as its lower part. The IL is formed on the exposed surfaces of protruding semiconductor fins 26’ and protruding dielectric fins 46. The IL may include an oxide layer such as a silicon oxide layer, which is formed through the thermal oxidation of protruding semiconductor fins 26’, a chemical oxidation process, or a deposition process. Gate dielectric 72 may also include a high-k dielectric layer formed over the IL. The high-k dielectric layer includes a high-k dielectric material such as hafnium oxide, lanthanum oxide, aluminum oxide, zirconium oxide, or the like. The dielectric constant (k-value) of the high-k dielectric material is higher than 3.9, and may be higher than about 7.0. The high-k dielectric layer is overlying, and may contact, the IL. The high-k dielectric layer is formed as a conformal layer. In accordance with some embodiments of the present disclosure, the high-k dielectric layer is formed using ALD, CVD, PECVD, Molecular-Beam Deposition (MBD), or the like.

A gate electrode 74 is formed on the respective gate dielectric 72. Gate electrode 74 may include a plurality of metal-containing layers, which may be formed as conformal layers, and may (or may not) include a filling-metal region filling the rest of the trenches unfilled by the plurality of metal-containing layers. The metal-containing layers may include a barrier layer, a work-function layer over the barrier layer, and one or a plurality of metal capping layers over the work-function layer.

FIG. 10B illustrates the cross-section in which gate stacks 76 are located. The gate stacks 76 of neighboring FinFETs are separated from each other by isolation regions 78, which cut the otherwise long gate stacks into shorter gate stacks 76. FIG. 10C illustrates the cross-section in which source/drain regions 62 are located. The top surface level 48T and bottom surface level 48B of STI regions 48, which are not in the illustrated plane in FIG. 10C, are shown to mark where STI regions 48 are.

In accordance with some embodiments, the STI capping layer 34 throughout the entire wafer 10 is formed in a same process. In accordance with alternative embodiments, the STI capping layer 34 in different device regions may be deposited in different processes. For example, FIG. 15 illustrates FinFET regions 100A and 100B, wherein the STI capping layer 34A in FinFET region 100A and the STI capping layer 34B in FinFET region 100B are formed in separate deposition processes. The dielectric layers 32, 36, and 38 in FinFET regions 100A and 100B may be formed sharing common processes. These embodiments may be used when the bending of fins in FinFET regions 100A and 100B are different from each other, and hence STI capping layers 34A and 34B are configured to apply different stresses. For example, when the inner-group spacing S1A is different from inner-group spacing S1B, and/or the materials of semiconductor strips 26A and 26B are different from each other, the bending of semiconductor strips 26A may be different from the bending of semiconductor strips 26B, which bending are fixed by STI capping layers 34A and 34B.

In accordance with some embodiments, STI capping layers 34A may have a first thickness T3A smaller than the thickness T3B of STI capping layers 34B. Accordingly, the stress applied by STI capping layers 34A is smaller than the stress applied by STI capping layer 34B. Alternatively, STI capping layers 34B have a higher nitrogen atomic percentage than STI capping layers 34A. This may be achieved, for example, by increasing the flow rate and the partial pressure of ammonia in the ALD cycles 35 as shown in FIG. 11. Accordingly, in the structure as shown in FIG. 15, the nitrogen atomic percentage in STI capping layers 34B is also higher that in STI capping layers 34A.

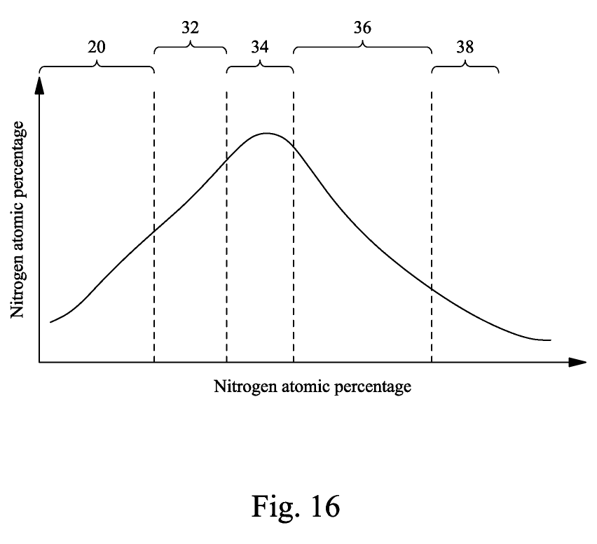

FIG. 16 Schematically illustrates the nitrogen distribution in accordance with some embodiments. The X-axis represents the depth along the arrow 80 in FIG. 10B. The Y-axis represents the nitrogen atomic percentage. In accordance with some embodiments, the nitrogen has a peak nitrogen atomic percentage in STI capping layer 34, and the nitrogen atomic percentage reduces from STI capping layer 34 into dielectric capping layer 36 and dielectric fin layer 38. The nitrogen atomic percentage may also reduce from STI capping layer 34 into dielectric layer 32 and substrate 20.

The embodiments of the present disclosure have some advantageous features. By forming a dielectric layer including nitrogen and also has the ability of losing nitrogen through annealing, the nitrogen-containing dielectric layer has the ability of applying a stress to reduce semiconductor strip/fin bending, while after the removal of nitrogen through the anneal, the resulting silicon oxide layer has low leakage due to the low charge-trapping. This is different from related structures in which either silicon oxide or silicon nitride (or silicon oxynitride) is formed. If silicon oxide is formed, it has no ability to reduce fin bending. If silicon nitride or silicon oxynitride is formed using related methods, it will stay as silicon nitride or silicon oxynitride, and will not be able to be converted into silicon oxide. The leakage current thus will be high.

In accordance with some embodiments of the present disclosure, a method comprises etching a semiconductor substrate to form a semiconductor strip and a recess, with a sidewall of the semiconductor strip being exposed to the recess; depositing a dielectric layer into the recess; depositing a capping layer over the dielectric layer, wherein the capping layer extends into the recess, and the capping layer comprises silicon oxynitride; filling remaining portions of the recess with dielectric materials; performing an anneal process to remove nitrogen from the capping layer; and recessing the dielectric materials, the capping layer, and the dielectric layer, wherein remaining portions of the dielectric materials, the capping layer, and the dielectric layer form an isolation region, and wherein a portion of the semiconductor strip protrudes higher than a top surface of the isolation region to form a semiconductor fin.

In an embodiment, the depositing the capping layer comprises an ALD cycle comprising pulsing HCD to the semiconductor substrate and purging; pulsing oxygen to the semiconductor substrate and purging; and pulsing ammonia to the semiconductor substrate and purging. In an embodiment, the method further comprises, after the recess is filled with the dielectric materials, performing a planarization process on the dielectric materials, the capping layer, and the dielectric layer, wherein the anneal process is performed through exposed top edges of the capping layer. In an embodiment, the anneal process is performed before the recessing. In an embodiment, the anneal process comprises a low-temperature wet anneal process performed at a first temperature; a high-temperature wet anneal process performed at a second temperature higher than the first temperature; and a dry anneal process performed after the high-temperature wet anneal process.

In an embodiment, the dry anneal process is performed at a third temperature higher than the first temperature and the second temperature. In an embodiment, the low-temperature wet anneal process is performed at the first temperature in a range between about 440°C and about 460°C. In an embodiment, the high-temperature wet anneal process is performed at the second temperature in a range between about 525°C and about 575°C. In an embodiment, the dry anneal process is performed at a third temperature in a range between about 650°C and about 750°C.

In accordance with some embodiments of the present disclosure, a method comprises forming a semiconductor strip; depositing a first dielectric layer through a plurality of ALD cycles, wherein each of the ALD cycles comprises pulsing HCD to the semiconductor strip and purging; pulsing oxygen to the semiconductor strip and purging; and pulsing ammonia to the semiconductor strip and purging; annealing the first dielectric layer; recessing the first dielectric layer, wherein a remaining portion of the first dielectric layer forms a part of an isolation structure, and a portion of the semiconductor strip protrudes higher than a top surface of the isolation structure to form a semiconductor fin; and forming a gate stack extending on a sidewall and a top surface of the semiconductor fin.

In an embodiment, in the each of the ALD cycles, the oxygen is pulsed after the HCD is pulsed, and the ammonia is pulsed after the oxygen is pulsed. In an embodiment, the method further comprises depositing additional dielectric layers over the first dielectric layer, wherein when the first dielectric layer is annealed, a top edge of a vertical portion of the first dielectric layer is exposed, and a horizonal portion of the first dielectric layer is underlying the additional dielectric layers. In an embodiment, the additional dielectric layers comprise silicon oxide and having a lower nitrogen atomic percentage than the first dielectric layer.

In an embodiment, the method further comprises, before the first dielectric layer is deposited, depositing a second dielectric layer, wherein the second dielectric layer comprises silicon oxide and has a lower nitrogen atomic percentage than the first dielectric layer. In an embodiment, the annealing the first dielectric layer comprises a low-temperature wet anneal process, a high-temperature wet anneal process, and a dry anneal process. In an embodiment, before the annealing, the first dielectric layer has a first nitrogen atomic percentage, and after the annealing, the first dielectric layer has a second nitrogen atomic percentage lower than the first nitrogen atomic percentage.

In accordance with some embodiments of the present disclosure, a method comprises depositing a first silicon oxide layer; depositing a silicon oxynitride layer over the first silicon oxide layer; depositing a second silicon oxide layer over the silicon oxynitride layer; and after the second silicon oxide layer is deposited, performing a first wet anneal process and a dry anneal process to convert the silicon oxynitride layer into a third silicon oxide layer. In an embodiment, the method further comprises, after the first wet anneal process and before the dry anneal process, performing a second wet anneal process using a temperature different from temperatures of the first wet anneal process and the dry anneal process.

In an embodiment, the method further comprises, after the first wet anneal process and the dry anneal process, etching back the first silicon oxide layer, the silicon oxynitride layer, and the second silicon oxide layer. In an embodiment, after the first wet anneal process and the dry anneal process, the third silicon oxide layer has a nitrogen atomic percentage higher than nitrogen atomic percentage of the first silicon oxide layer and the second silicon oxide layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
etching a semiconductor substrate to form a semiconductor strip and a recess;
forming a shallow trench isolation region comprising:
depositing a dielectric layer;
depositing a capping layer over the dielectric layer, wherein the capping layer comprises silicon oxynitride; and
depositing dielectric materials over the capping layer, wherein the dielectric layer, the capping layer and the dielectric materials comprise portions in the recess; recessing the dielectric materials, the capping layer, and the dielectric layer, wherein remaining portions of the dielectric materials, the capping layer, and the dielectric layer form the shallow trench isolation region; and
performing an anneal process to remove nitrogen from the capping layer.

2. The method of claim 1, wherein the anneal process is performed in a process gas, and wherein during the anneal process, the process gas is in physical contact with a top surface of the semiconductor strip.

3. The method of claim 1, wherein when the anneal process is performed, a first top surface of the semiconductor strip is coplanar with a second top surface of the dielectric materials.

4. The method of claim 1 further comprising forming a transistor based on the semiconductor strip and the shallow trench isolation region.

5. The method of claim 1, wherein during the anneal process, a top surface of the semiconductor strip is exposed.

6. The method of claim 1, wherein the dielectric materials are recessed so that a portion of the semiconductor strip protrudes higher than a top surface of the shallow trench isolation region to form a semiconductor fin.

7. The method of claim 1, wherein after the anneal process, the capping layer and the dielectric layer comprise a same dielectric material, and are in physical contact with each other.

8. The method of claim 7, wherein both of the capping layer and the dielectric layer comprise silicon oxide.

9. The method of claim 1, wherein the depositing the capping layer comprises an Atomic Layer Deposition (ALD) cycle comprising:
pulsing Hexachlorodisilane (HCD) to the semiconductor substrate and purging;
pulsing oxygen to the semiconductor substrate and purging; and
pulsing ammonia to the semiconductor substrate and purging.

10. The method of claim 1 further comprising:
after the recess is filled with the dielectric materials, performing a planarization process on the dielectric materials, the capping layer, and the dielectric layer, wherein the anneal process is performed through exposed top edges of the capping layer.

11. A method comprising:
forming a semiconductor strip;
depositing a first dielectric layer through a plurality of Atomic Layer Deposition (ALD) cycles, wherein each of the ALD cycles comprises:
pulsing Hexachlorodisilane (HCD) to the semiconductor strip and purging; pulsing oxygen to the semiconductor strip and purging; and
pulsing ammonia to the semiconductor strip and purging;
depositing a second dielectric layer over the first dielectric layer, wherein the second dielectric layer comprise nitrogen therein;
performing a planarization process to remove a top portion of the second dielectric layer, wherein the top portion of the second dielectric layer overlaps the semiconductor strip; and
annealing the first dielectric layer to remove nitrogen atoms from the first dielectric layer.

12. The method of claim 11, wherein the annealing results in a dielectric constant of the first dielectric layer to be lowered.

13. The method of claim 11 further comprising:
recessing the first dielectric layer, wherein a remaining portion of the first dielectric layer forms a part of an isolation structure, and a portion of the semiconductor strip protrudes higher than a top surface of the isolation structure to form a semiconductor fin; and
forming a gate stack on the semiconductor fin.

14. The method of claim 11, wherein the planarization process results in a top surface of the semiconductor strip to be exposed, and during the annealing the first dielectric layer, the top surface of the semiconductor strip is exposed to a process gas used for the annealing.

15. The method of claim 11 further comprising, before the planarization process, depositing a dielectric fin layer over the second dielectric layer.

16. The method of claim 11, wherein the second dielectric layer comprises silicon oxide, and has a lower nitrogen atomic percentage than the first dielectric layer.

17. A method comprising:
forming a recess on a side of a semiconductor trip;
depositing a first silicon oxide layer, with a first portion of the first silicon oxide layer in the recess;
depositing a silicon-and-oxygen containing layer over the first silicon oxide layer, with a second portion of the silicon-and-oxygen containing layer being in the recess, wherein the silicon-and-oxygen containing layer is in contact with the first silicon oxide layer;
depositing a second silicon oxide layer over the silicon-and-oxygen containing layer; and
after the second silicon oxide layer is deposited, performing an anneal process to reduce a dielectric constant of the silicon-and-oxygen containing layer.

18. The method of claim 17, wherein when the silicon-and-oxygen containing layer is annealed, a top surface of the semiconductor strip is exposed to a process gas used for the annealing.

19. The method of claim 17, wherein the first silicon oxide layer and the silicon-and-oxygen containing layer are deposited through different deposition methods, and after the anneal process, the first silicon oxide layer and the silicon-and-oxygen containing layer comprise a same dielectric material.

20. The method of claim 17 further comprising:
performing a planarization process to planarize the first silicon oxide layer, the silicon-and-oxygen containing layer, and the second silicon oxide layer; and
recessing the first silicon oxide layer and the silicon-and-oxygen containing layer, wherein the anneal process is performed at a time between the planarization process and the recessing.
